(19) United States
(12) Patent Application Publication
(10) Pub. No.: US 2011/0210708 A1
(43) Pub. Date: Sep. 1, 2011

(54) High Frequency Power Supply Module Having High Efficiency and High Current

(75) Inventors: Juan A. HERBSOMMER, Schnecksville, PA (US); Osvaldo J. LOPEZ, Annadale, NJ (US); Jonathan A. NOQUIL, Lapu Lapu City Cebu (PH); David JAUREGUI, Bethlehem, PA (US); Christopher B. KOCON, Mountain Top, PA (US)

(73) Assignee: TEXAS INSTRUMENTS INCORPORATED, Dallas, TX (US)

(21) Appl. No.: 12/942,871

(22) Filed: Nov. 9, 2010

Related U.S. Application Data
(60) Provisional application No. 61/309,309, filed on Mar. 1, 2010.

(51) Int. Cl. G05F 1/10; H01L 21/50

(52) U.S. Cl. 323/271; 438/123; 257/E21.499

(57) ABSTRACT

A high frequency power supply module (200) of a synchronous Buck converter stacking the control FET (210) and sync FET (220) and having the driver IC (230) integrated in the final package solution. A QFN leadframe has a rectangular flat pad (201) destined to become the heat spreader of the package; the leads (202) are positioned in line with two opposite sides of the pad, the other pad sides being free of leads. The sync FET die (220) is soldered to the pad; a first clip (240), soldered on the sync die, has the control die (210) attached by solder. A second clip (260) is soldered on top of the control die. Also soldered on the same pad, yet not stacked with the other dies, is IC driver chip (230). The IC driver is wire bonded (233) to the pins of the package and to the stacked dies. All die attach and clip attach use the same solder material in order to be reflowed in the same reflow step.

### FIELD OF THE INVENTION

The present invention is related in general to the field of semiconductor devices and processes, and more specifically to the system structure and fabrication method of a small-size power supply system having high efficiency and operating at high frequency and high current.

### DESCRIPTION OF RELATED ART

Among the popular families of power switching devices are the DC-DC power supply circuits, especially the category of Switched Mode Power Supply circuits. Particularly suitable for the emerging power delivery requirements are the synchronous Buck converters with two power MOS field effect transistors (FETs) connected in series and coupled together by a common switch node. In the Buck converter, the control FET die, also called the high side switch, is connected between the supply voltage V_{IN} and the LC output filter, and the synchronous (sync) FET die, also called the low side switch, is connected between the LC output filter and ground potential (the sync FET works as a synchronous rectifier substituting for a free wheeling diode).

The gates of the control FET die and the sync FET die are connected to a semiconductor chip including an integrated circuit (IC) acting as the driver of the converter, and the driver, in turn, is connected to a controller IC. Preferably, both ICs are integrated on a single chip, which is also connected to ground potential.

The inductor of the output circuitry serves as the energy storage of the power supply circuit. Consequently, the inductor has to be a large enough component (typical sizes are 300 to 400 nH) to reliably function for maintaining a constant output voltage V_{OUT}. Based on the sizeable inductance, the output inductor inherently includes parasitic resistance, which is a partial cause of power loss at the board level.

For many of today's power switching devices, the dies of the power MOSFETs and the driver chip and the controller IC are assembled as individual components, typically attached to a rectangular or square-shaped pad of a metallic leadframe, surrounded by leads as output terminals. The leads are commonly shaped, for example, without cantilever extensions and arranged in the manner of Quad Flat No-Lead (QFN) or Small Outline No-Lead (SON) devices. The electrical connections from the dies and the chip to the leads are provided by bonding wires (made of gold), which inherently incorporate, due to their lengths and resistances, significant parasitic inductance into the power circuit. The assembly is typically packaged in a plastic encapsulation, and the packaged components are employed as discrete building blocks for board assembly of power supply systems.

In other power switching devices, the power MOSFET dies and the driver-and-controller IC are assembled horizontally side-by-side on a leadframe pad, which in turn is surrounded on all four sides by leads serving as device output terminals. The leads are shaped, for example, in QFN or SON fashion. The electrical connections between the dies, the chip, and the leads are provided by bonding wires made of gold, which incorporate, due to their lengths and resistances, significant parasitic inductance into the power circuit. The devices are packaged in a plastic encapsulation.

In some recently introduced assemblies, clips made of copper substitute for many connecting wires. These clips are wide and introduce less parasitic inductance. However, in power MOSFET dies with vertical current flow, clips need to connect the front metal of the high side switch to the leadframe of the low side switch. This approach consumes area and increases the footprint of the module. In another recently introduced scheme, the control FET die and the sync FET die are assembled vertically on top of the other as a stack. In this assembly, at least one MOSFET die is configured for vertical current flow; the source electrode of the control FET die is facing the drain electrode of the sync FET die.

### SUMMARY OF THE INVENTION

Applicants recognized that operating the synchronous Buck converter at a higher frequency, for example, 1 MHz instead of at 500 kHz and at substantially unchanged output current and efficiency would allow a customer to reduce transient time response to load and thus the number of passive components, such as capacitors surrounding the converter, saving board real estate and reducing heat generation. The customer could further be able to reduce the inductance of the output inductor to have the same ripple current, thus lowering parasitic resistance value of the inductor and reducing power loss at the board level. Applicants further recognized that the frequency can also be increased by reducing the power loss:

$$\begin{matrix}efficiency = output power / input power \\ = output power / ( output power - power loss )\end{matrix}$$

Since the power loss in a synchronous Buck converter is determined by:

power loss=I_{L}²R+P_{SW}

(wherein I_{L}=load current, R=intrinsic resistance, P_{SW}=switching loss), applicants solved the problem of reducing the power loss and increasing the efficiency by proceeding along two approaches: Reducing switching loss and thus heat generation at the device level, and improving heat dissipation at the board level.

Applicants' analysis showed that P_{SW} can be reduced by eliminating parasitic inductances presently existing in many places due to a 2-dimensional methodology of assembling the control FET die, the sync FET die, and the driver chip. Applicants' fine-tuned and partially 3-dimensional integration of the components into a single package not only eliminates inductive and parasitic resistance but also shrinks the module dimensions and at the same time avoids assembly disadvantages such as downhill wire bonding. In particular, applicants use the assembly pad of the leadframe as an effective heat spreader by positioning the leads of the leadframe in line with only two opposite sides of the pad so that they do not block the thermal flow from the pad to a heat sink on the board. Further, the pad is soldered to the heat sink using the same solder and reflow process as for all other attachments of the Buck converter, thus eliminates the traditional epoxy attachments.

One embodiment of the invention is a high frequency power supply module, in which a synchronous Buck converter configuration is realized by stacking the control FET and sync FET with the proper interconnects to the external package pinout and the driver IC is also integrated in the final package solution. The sync FET is attached to a flat leadframe pad destined to become a heat spreader of the package. A top clip is attached on top of the sync die. On top of the clip the control die of the Buck converter is attached. On top of the control die another clip is placed to make the proper electrical connection to the package pins. On the same pad, yet not stacked with the other dies, an IC driver is also attached. The IC driver is wire bonded to the stacked dies and to the pins of the package. All die attach and clip attach can use the same solder material as interconnect in order for both dies and clips to be reflowed together in the same reflow step.

Another embodiment of the invention is a process flow to assemble and package a high frequency power supply module with QFN outline. In a first step, solder paste is used to place the driver and controller chip with its solderable back side metallization on the solderable surface of the leadframe pad. In the next step, solderpaste is used to place the solderable bottom (preferably the source) terminal of the sync FET die on the pad. Next, using solder paste, a first preformed clip is placed on the top terminal of the sync die and on respective leads. Then the solderable bottom (preferably the source) terminal of the control FET die is placed with solder paste on the first clip. Next, using solder paste, a second preformed clip is placed on the top terminal of the control die and on respective leads.

Thermal energy is added to reach the reflow temperature of the common solder paste for creating all solder joints simultaneously and attaching all parts in the same step. After cool down and clean up, wire bonding is the preferred technique to interconnect the IC chip with the FET dies and the leads. Finally, a molding technique encapsulates the wire bonds, chip, dies and leads in a plastic compound to leave only the bottom sides of pad and leads un-encapsulated and available for solder attachment to and external board and heat sink.

### BRIEF DESCRIPTION OF THE DRAWINGS

FIG. 1 displays a circuit diagram of a synchronous Buck converter in a conventional layout to identify electrical parasitics arising in the power supply module.

FIG. 2 illustrates a perspective top view of a synchronous Buck converter assembled in an integrated module according to an embodiment of the invention.

FIG. 3 is a perspective bottom view of a synchronous Buck converter assembled in an integrated module according to an embodiment of the invention.

FIG. 4 displays a circuit diagram of a synchronous Buck converter in the integrated layout according to an embodiment of the invention to identify the elimination of electrical parasitics in a conventional power supply module.

FIG. 5 is a plot of power loss as a function of output current in synchronous Buck converters, comparing the performance of a module assembled according to the invention with the performance of conventionally assembled modules.

FIG. 6 is a plot of efficiency as a function of output current in synchronous Buck converters, comparing the performance of a module assembled according to the invention with the performance of conventionally assembled modules.

FIG. 7 is a plot of efficiency as a function of output current in synchronous Buck converters, comparing the performance of a module assembled according to the invention and operating at a switching frequency of 1 MHz with the performance of a conventionally assembled module operating at 500 MHz.

FIG. 8 illustrates the method for assembling a synchronous Buck converter according to another embodiment of the invention.

### DETAILED DESCRIPTION OF THE PREFERRED EMBODIMENTS

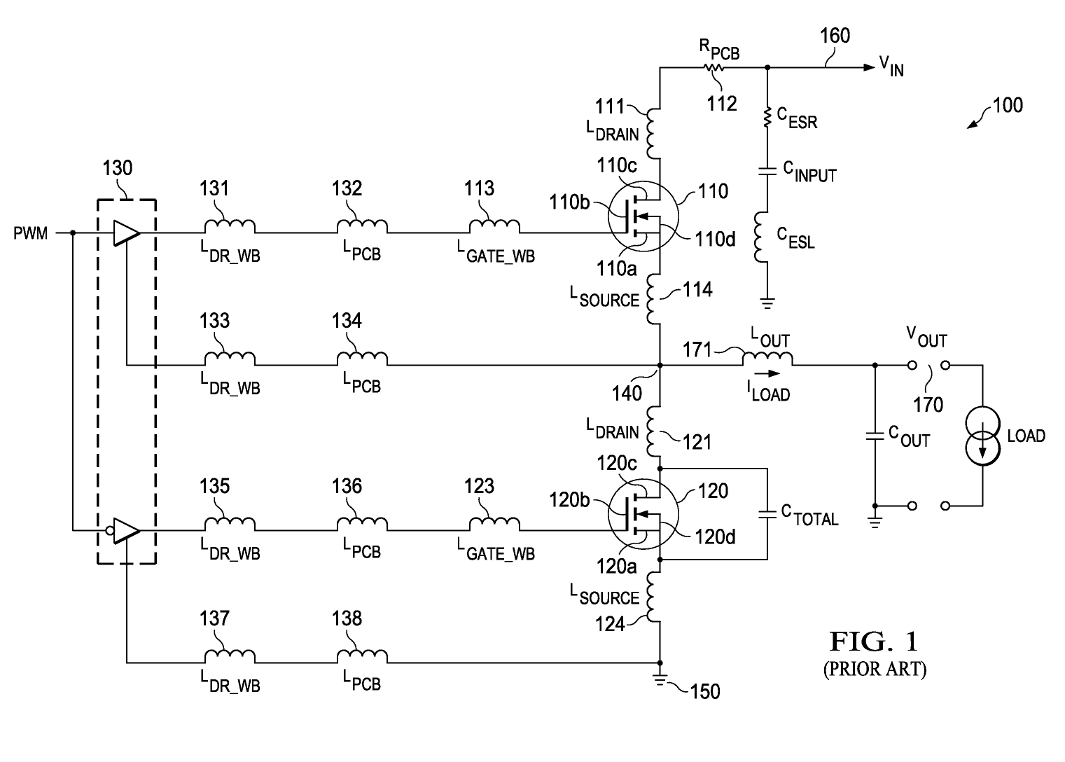

To identify the electrical parasitics arising in the power supply module generally designated 100, the circuit diagram of FIG. 1 displays the assembly of discrete components in a conventional layout of a synchronous Buck converter. The control power MOS field effect transistor (FET), also called high side switch or high side die is 110; the synchronous power MOSFET, also called sync FET, low side switch, or low side die is 120. In FIG. 1, both FETs are shown as n-channel transistors. The integrated circuit (IC) of the driver and controller chip is 130.

Drain 110c of the control FET 110 is connected to the input V_{IN} (160); the connection includes inductance L_{DRAIN} (111) and impedance R_{PCB} (112). It should be noted that herein subscripts PCB denote origination from the printed circuit board. Source 110a of the control FET 110 is tied via common switch node 140 to drain 120c of the sync FET 120. Back gate 110d of the control FET is also connected to switch node 140. The connection of source 110a to switch node 140 encounters parasitic inductance L_{SOURCE} (114), also called common source inductance L_{CS}, typically about 0.5 nH. The connection of switch node 140 to source 120c encounters parasitic inductance L_{DRAIN} (121), typically about 0.5 nH. Gate 110b of control FET 110 is coupled to driver 130; this connection includes inductance L_{GATE}_{_{—}}_{WB} (113) of about 1.5 nH, parasitic inductance L_{PCB} (132) of about 5.0 nH in conjunction with the board, and driver-related parasitic inductance L_{DR}_{_{—}}_{WB} (131) of about 1.5 nH. It should be noted that herein subscripts WB devote origination from wire bonding. The connection of common switch node 140 to driver 130 includes parasitic inductance L_{PCB} (134) of about 5.0 nH and parasitic inductance L_{DR}_{_{—}}_{WB} (133) of about 1.5 nH. Back gate 120d of the sync FET is connected to ground.

Source 120a of the sync FET 120 is tied to electrical ground 150; this connection includes parasitic inductance L_{SOURCE} (124) of about 0.5 nH. Gate 120b of the sync FET 120 is coupled to driver 130, this connection includes inductance L_{GATE}_{_{—}}_{WB} (123) of about 1.5 nH, parasitic inductance L_{PCB} (136) of about 5.0 nH, and driver-related parasitic inductance L_{DR}_{_{—}}_{WB} (135) of about 1.5 nH. The connection of driver 130 to ground 150 includes parasitic inductance L_{DR}_{_{—}}_{WB} (137) of about 1.5 nH and parasitic inductance L_{PCB} (138) of about 5.0 nH.

Switch 140 is coupled to output inductor 171, which has an inductance L_{OUT} of approximately 300 nH. Inductor 171 serves as the energy storage of the power supply system, which has to be large enough to reliably function for maintaining a constant output voltage V_{OUT} (170). Due to its size, output inductor 171 not only consumes board area, but also includes substantial parasitic resistance, which results in power loss at the board level.

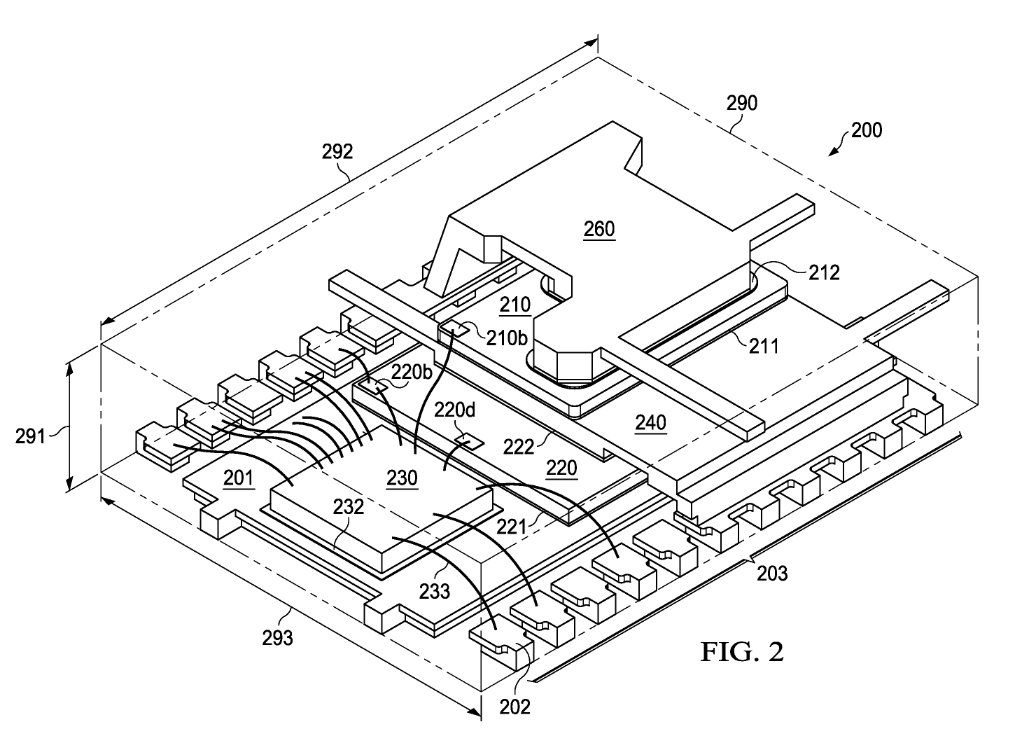

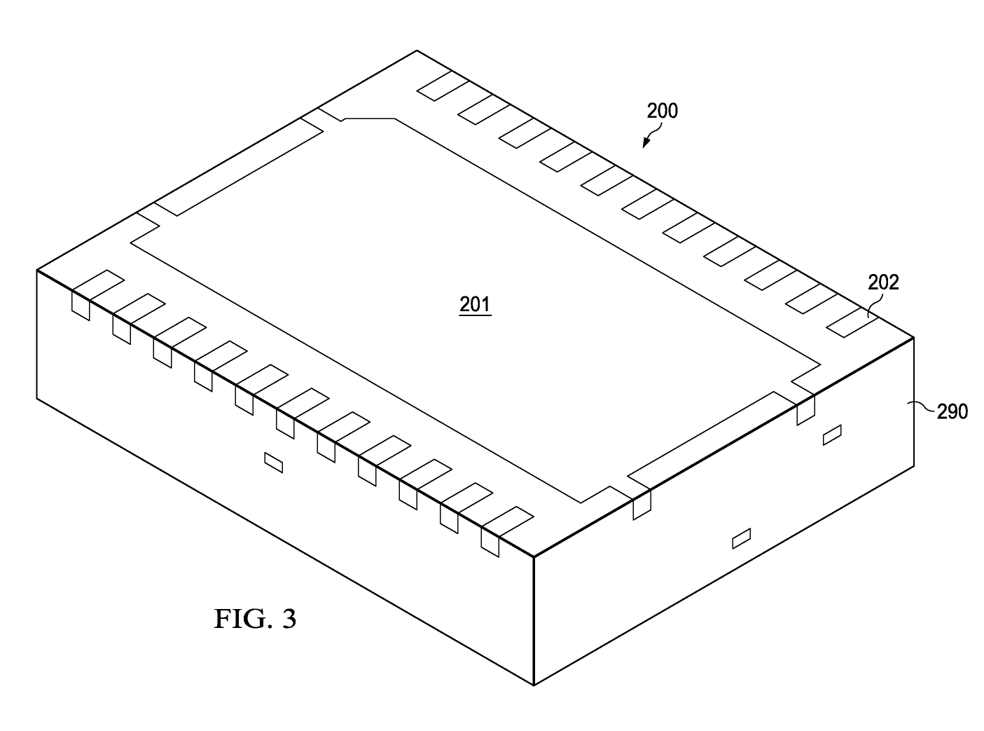

FIG. 2 illustrates a simplified perspective view of a power supply module designated 200 as an exemplary embodiment of the invention. For explanatory reasons, module 200 is shown with a transparent encapsulation 290. Preferred actual encapsulation uses a black-colored epoxy formulation (see FIG. 3) for a transfer molding technology. The exemplary module of FIG. 2 has a thickness 291 of 1.5 mm, a module length 292 of 6 mm and a module width 293 of 5 mm. Visible through the transparent encapsulation is a metal leadframe generally suitable for Quad Flat No-Lead (QFN) and Small Outline No-Lead (SON) type modules. The leadframe includes a rectangular pad 201 and a plurality of leads 202 parallel to two opposite sides of the pad positioned in lines 203; the other sides of the pad maybe free of leads. The leadframe is preferably made of copper or a copper alloy; alternative metal selections include aluminum, iron-nickel alloys, and Kovar™. Both surfaces of the leadframe may be prepared to facilitate solder attachment, for instance, by a sequence of plated layers of nickel, palladium, and gold. In addition, the at least one surface may have a metal layer deposited to enhance thermal conductivity, for instance, by a plated layer of silver. Preferred thickness of the leadframe metal for the exemplary embodiment shown in FIG. 2 is 0.2 mm; other embodiments may use thinner or thicker leadframe metal. From the standpoint of low cost and batch processing, it is preferred to start with sheet metal and fabricate the leadframe as a strip by stamping or etching, and to singulate the leadframe for the module by trimming the strip after the encapsulation process.

FIG. 2 shows the control FET die and the sync FET die assembled as a vertical stack and attached to pad 201. The low side die 220 of the sync FET has the source terminal soldered onto pad 201 by solder attach layer 221. For the embodiment shown in FIG. 2, low side die 220 has a size of about 3.5×2.84 mm, and a thickness of 0.1 mm. For other embodiments, the die size and the die thickness may be significantly smaller or greater. The preferred thickness of layer 221 is at least 25 μm. The solder material, which maybe a solder paste, is selected so that the same material can be used for all solder joints of the power supply module, allowing a single solder reflow step for assembling the module.

In FIG. 2, the sync FET terminals, which are metallurgically suitable for wire bonding, are designated 220b for the gate and 220d for the gate return. The drain terminal is coupled by solder layer 222 to first clip 240, which represents the common switch node. Preferred thickness of solder layer 222 is 25 μm or more. As FIG. 2 shows, first clip 240 has a structure to function as common switch node between the drain of the low side die and the source of the high side die and also as low impedance contact of the switch node to a plurality of leads capable of conducting the load current to the output inductor. First clip 240 is preferably made of copper in the thickness range from about 0.2 to 0.3 mm; both surfaces of first clip 240 are preferably solderable. First clip 240 is preferably employed in strip form and etched to acquire its contours and thicknesses; the strip is trimmed after encapsulating the module in compound 290, leaving the tie bars shown in FIG. 2 as residues.

Vertically attached to the top surface of first clip 240 is the source of high side die 210 of the control FET. For the embodiment shown in FIG. 2, high side die 210 has a size of about 2.5×1.8 mm, and a thickness of 0.1 mm. For other embodiments, the die size and the die thickness may significantly be of smaller or greater values. Solder attach layer 211 has a thickness of about 25 μm or more. In FIG. 2, the control FET terminal metallurgically suitable for wire bonding is designated 210b. The drain terminal is coupled by solder layer 212 to second clip 260. Like the other solder joints, solder layer 212 has a thickness of about 25 μm or more. As FIG. 2 shows, second clip 260 has a structure to function as low impedance contact of the drain terminal of the control FET to the input supply, capable of conducting the input current. Second clip 260 is preferably made of copper in the thickness range from about 0.2 to 0.3 mm, more preferably about 2.5 mm. The bottom surface of second clip 260 is solderable. Second clip 260 is preferably employed in strip form and etched to acquire its contours and thicknesses; the strip is trimmed after encapsulating the module in compound 290, leaving the tie bars shown in FIG. 2 as residues.

As depicted in FIG. 2, in close proximity to the vertically stacked FET dies is silicon integrated circuit (IC) chip 230, providing driver and controller functions for the power supply system. In the exemplary embodiment of FIG. 2, the distance between chip 230 and die 220 is about 300 μm. Chip 230 has back side metallization (not shown in FIG. 2) to allow attachment to leadframe pad 201 by solder layer 232 (preferably about 25 μm thick). The metallic solder provides high thermal conductivity for spreading heat from chip 230 to pad 201. In the exemplary embodiment shown in FIG. 2, chip 230 is square shaped with side length about 1.4 to 1.5 mm and 0.2 mm thick. Other embodiments may have chips, which are smaller or greater, and thicker or thinner. For example, in some modules chip 230 and dies 220 and 210 have the same thickness.

As FIG. 2 shows, the terminals of chip 230 are bonded by wires 233 to the respective leads and die terminals. If the chip 230 is narrower than or similar to chip 220, the distance between the leads and the terminals on the chip 230 may stretch the wire spans such that any height difference due to the thickness of chip 230 becomes insignificant. Consequently, the wire connections 233 can be provided without the downhill-bonding concern of the bond wire shorting to the edge of the chip; and therefore enhancing the reliability of the module assembly. The preferred diameter of bonding wires 233 is about 25 μm, but may be smaller or greater.

FIG. 3 shows a bottom view of exemplary QFN-shaped module 200. Leadframe pad 201 and leads 202 are exposed from encapsulation compound 290 and have solderable surfaces. As stated above, pad 201 is rectangular and leads 202 are positioned in line with two opposite sides of pad 201, while the other pad sides are free of leads. Based on the high thermal conductivity of the leadframe metal, pad 201 acts as heat spreader of module 200. Pad 201 is preferably soldered onto a heat sink, which is a portion of the top metal layer of a substrate. Preferred substrates are multi-metal-layer laminate. With the sides of pad 201 free of leads the heat sink can extend beyond the edges of the module in a continuous fashion with being interrupted by leads and therefore can dissipate the heat generated by the module during operation more effectively. Due to its wide expanse, the top metal layer thus as an effective heat sink. Based on the heat dissipation, module 200, in spite of its small size, is able to handle electrical currents in excess of what is achievable with a conventional module.

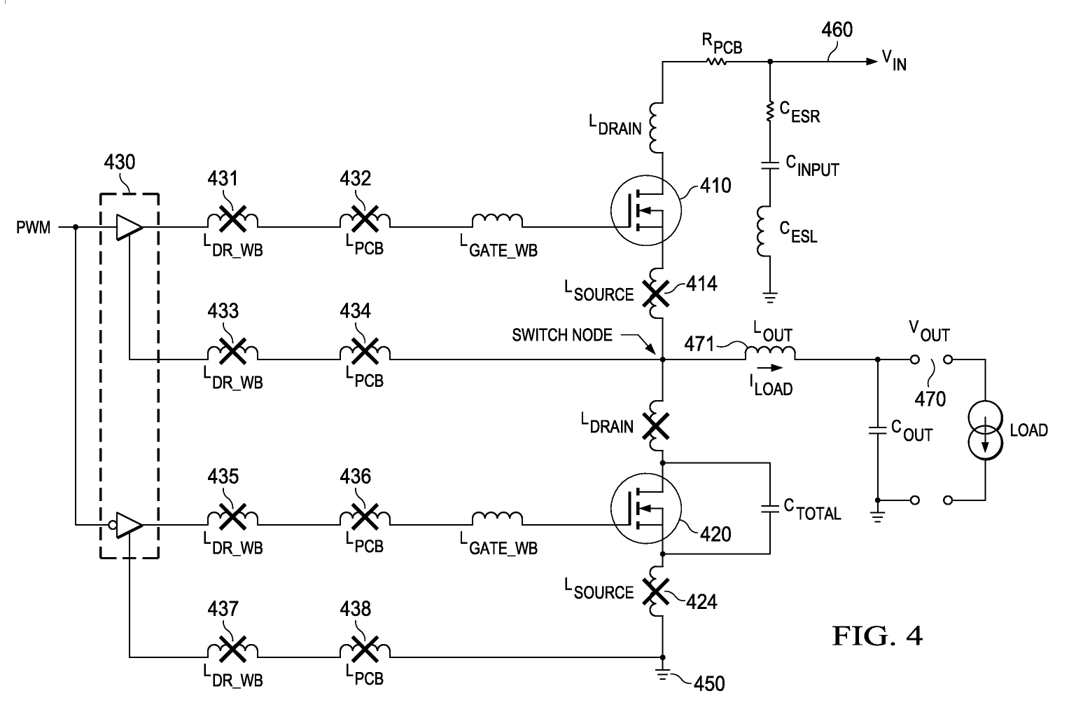

Assembling a synchronous Buck converter according to FIGS. 2 and 3 reduces parasitic inductances prevalent in conventional assembly. FIG. 4 specifies several improvements related to the vertical stacking of control FET die on sync FET die and to the proximity of the driver chip to the stacked FETs. FIG. 4 uses the following designations: input voltage 460, output voltage 470, inductance of output inductor 471, control FET 410, sync FET 420, driver and controller 430, ground potential 450.

The parasitic common source inductance L_{CS} (414, L_{SOURCE}), if allowed to exist, will degenerate the applied gate drive voltage V_{GS} to reduce effective voltage V_{EFF} across gate-to-source of the control FET:

V_{EFF}=V_{GS}−L_{CS}·dI_{DS}/dt,

wherein I_{DS} is the drain current.

Since the switching time t_{SW} of the control FET is an inverse function of the effective voltage V_{EFF}, the parasitic inductance L_{CS} can further increase the switching time t_{SW}, which in turn increases the switching losses P_{SW}:

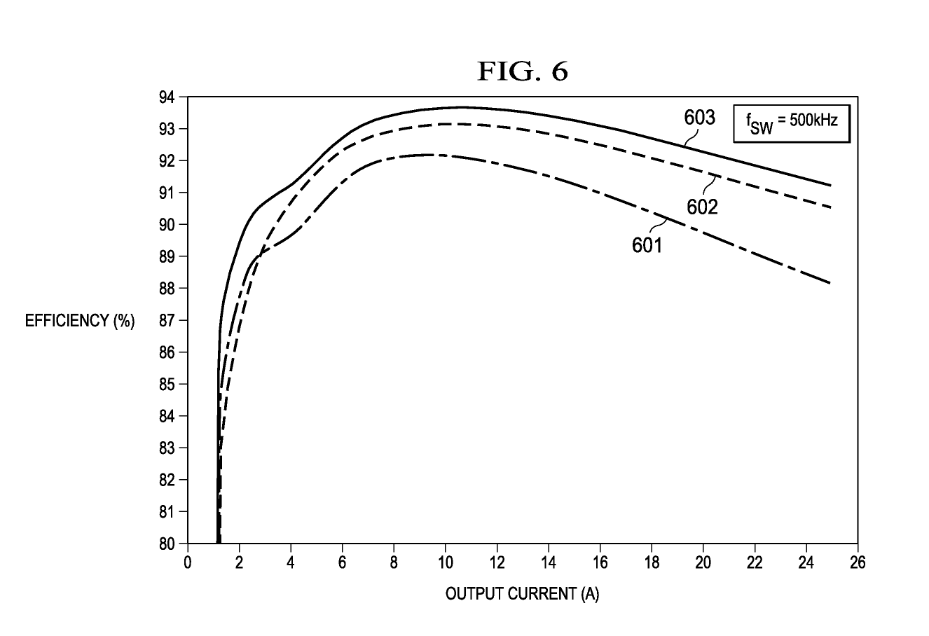

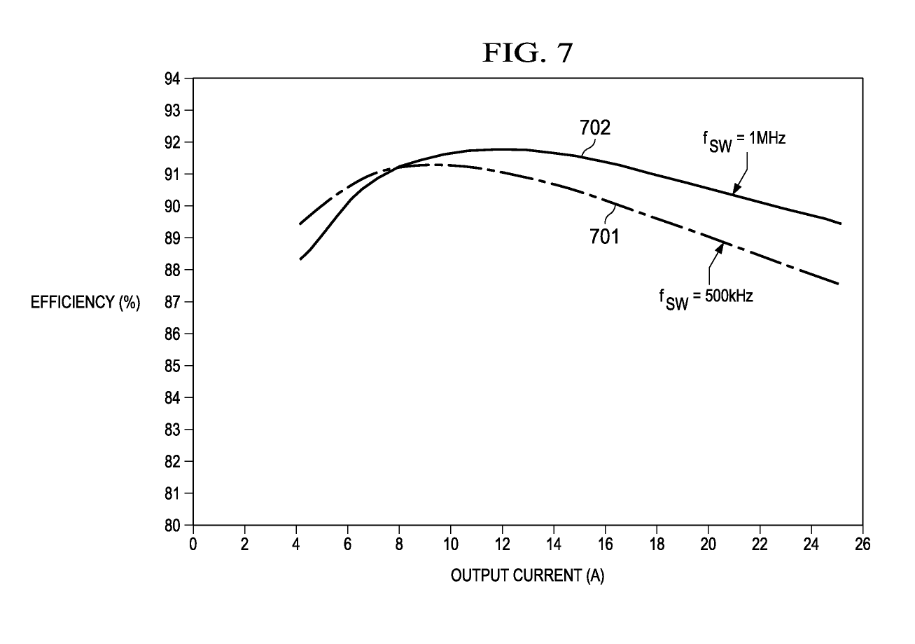

P_{SW}=V_{DS}·I_{DS}·t_{SW}·f_{SW},

wherein f_{SW} is the switching frequency of the synchronous Buck converter. Since the module assembly according to FIG. 2 eliminates the parasitic common source inductance L_{CS} of the conventional assembly, the cause-and-effect chain is inversed: The elimination of the parasitic common source inductance L_{CS} improves the effective voltage V_{EFF}, which in turn reduces the switching time t_{SW}, which in turn reduces the switching losses P_{SW}. As stated above, reduced switching losses P_{SW} drive reduced power losses, which in turn improve the efficiency of the converter. As further explained above, improved efficiency facilitates the option to operate the converter at higher frequency. This aspect will be discussed in more detail in FIGS. 6 and 7.

Relative to the control FET, the parasitic gate inductance L_{G} (distributed among 432 L_{DR}_{_{—}}_{WB}, 432 L_{PCB}, 433 L_{DR}_{_{—}}_{WB}, 434 L_{PCB}) has the ability to limit the applied gate drive current I_{G}. Limiting the applied gate drive current is driving an increase of switching losses P_{SW}:

P_{SW}=V_{DS}·I_{DS}·Q_{SW}/I_{G}·f_{SW},

wherein Q_{SW} is the gate electric charge determining switching time t_{SW}=Q_{SW}/I_{G}.

Since the module assembly according to FIG. 2 eliminates the parasitic gate inductance L_{G} relative to the control FET of the conventional assembly, the cause-and-effect chain is inversed. The elimination of the parasitic gate inductance L_{G} improves the applied gate drive current I_{G}, which in turn reduces the respective switching loss P_{SW}. As stated, reduced switching losses P_{SW} drive reduced power losses, which in turn improve the efficiency of the converter, and further, improved efficiency facilitates the option to operate the converter at higher frequency (discussed in more detail in FIGS. 6 and 7).

Relative to the sync FET, the switching speed of the control FET determines the dV/dt induced turn-on, which will create shoot-through. That is when both FETs are turned on, thus representing a short circuit and thus increase power loss. The parasitic gate inductance L_{G} of the sync FET, distributed among 435 L_{DR}_{_{—}}_{WB}, 436 L_{PCB}, 437 L_{DR}_{_{—}}_{WB}, 438 L_{PCB}, and 424 L_{SOURCE}, has the ability to worsen the turn-on by increasing the effective pull-down impedance R_{PD} of the driver IC:

R_{PD}=R_{DRIVER}+2πL_{G}/t_{SW},

wherein R_{DRIVER} is the intrinsic impedance of the driver IC.

Since the module assembly according to FIG. 2 eliminates the parasitic gate inductance L_{G} relative to the control FET of the conventional assembly, the cause-and-effect chain is inversed. The elimination of the parasitic gate inductance L_{G} reduces the effective pull-down impedance R_{PD} of the driver IC, which in turn improves the dV/dt induced turn-on and thus reduces power loss. As stated, reduced power loss improves the efficiency of the synchronous Buck converter, facilitating the option to operate the converter at higher frequency This aspect will also be discussed in more detail in FIGS. 6 and 7.

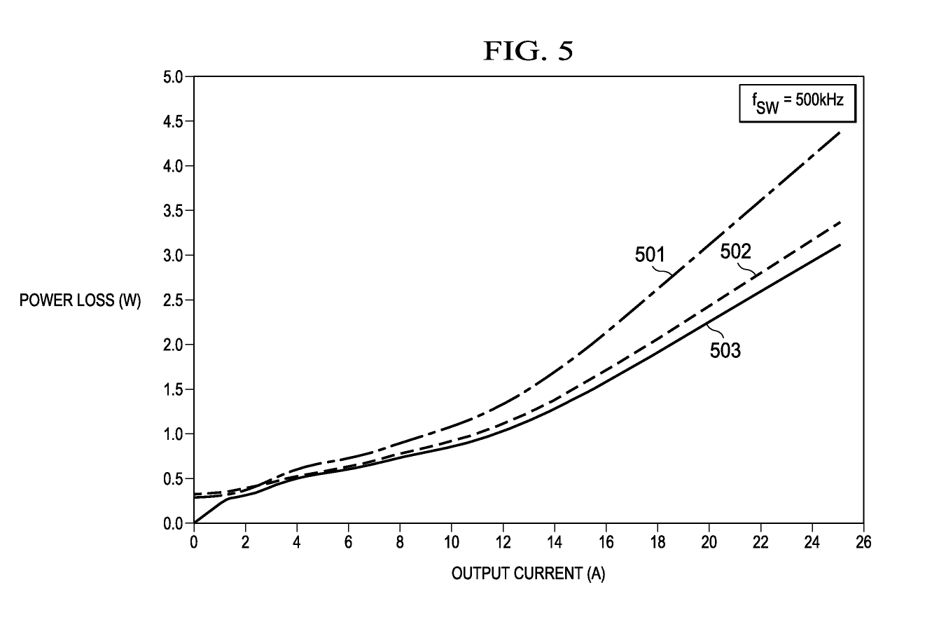

In order to illustrate the impact of assembling a synchronous Buck converter according to the invention, FIGS. 5 and 6 compare experimental data of such exemplary converter as illustrated in FIGS. 2 and 3 to data obtained from conventionally assembled Buck converters. All modules were operated at input voltage of V_{IN}=12 V, output voltage of V_{OUT}=1.3 V, inductance of output inductor of L_{OUT}=300 nH, switching frequency f_{SW}=500 kHz, and ambient temperature=25° C.

The plot of FIG. 5 depicts the power loss of comparable modules as a function of output current. Curve 501 is obtained for two discrete MOS FET dies assembled side by side on a leadframe pad with a separate driver chip; curve 502 is obtained for two MOS FET dies assembled vertically as a stack on a leadframe pad with a separate a driver chip; and curve 503 is obtained by an assembly of two MOS FET dies vertically as a stack on a leadframe pad with the driver chip adjacent and close to the stack on the same leadframe pad (FIG. 2). The data of FIG. 5 demonstrate that a converter module with transistor dies and driver chip assembled according to the invention (curve 503) shows the smallest power loss up to 25 A output current. Favored by the unobstructed heat dissipation of the leadframe pad soldered to a substrate heat sink. The more unpredicted result is that the superiority of the assembly according to FIG. 2 extends up to an output current of about 40 A, which a conventional module has not been able to deliver due to the heat dissipation problem.

The plot of FIG. 6 depicts the efficiency, defined by [output power/(output power−power loss)] and expressed in percent, of comparable modules as a function of output current. Curve 601 is obtained by an assembly of two discrete MOS FET dies assembled side by side on a leadframe pad with a separate driver chip; curve 602 is obtained by an assembly of two MOS FET dies assembled vertically as a stack on a leadframe pad with a separate driver chip; and curve 603 is obtained by an assembly of two MOS FET dies vertically as a stack on a leadframe pad with the driver chip on the same leadframe pad adjacent to and in proximity with the stack (FIG. 2). The data of FIG. 6 confirm that a module with the assembly according to the invention (curve 603) shows the highest efficiency up to 25 A output current. Favored by the unobstructed heat dissipation of the leadframe pad soldered to a substrate heat sink, recent data confirmed the superiority of the assembly according to FIG. 2 up to an output current of about 40 A.

Based on the lower power losses, the high efficiency of a synchronous Buck converter assembled according to the invention allows such converter to be operated at a switching frequency f_{SW} of 1 MHz instead of the conventional 500 kHz. FIG. 7 plots the efficiency as a function of the output current for input voltage V_{IN}=12 V, output voltage V_{OUT}=1.3 V, inductance of output inductor L_{OUT}=300 nH, and ambient temperature=25° C. Curve 701 is measured for two discrete MOS FET dies assembled side by side on a leadframe pad with a separate driver chip; curve 702 is measured for by an assembly of two MOS FET dies stacked vertically with the driver chip adjacent in close proximity on the same leadframe pad. As curve 702 shows, in spite of a switching frequency twice as high as the conventional frequency, the converter operates at substantially unchanged output current and efficiency due to the reduced power loss and improved thermal characteristics (heat spreading and dissipation). Based on the characteristics of curve 702, recent developments could indeed afford to reduce the output inductor to 150 nH from 300 nH. Further, by moving the output inductor in close proximity to the Buck converter assembly shown in FIG. 2 and reducing the number of passive components such as capacitors surrounding the converter, heat generation can further be reduced and board real estate can be saved, simplifying the layout design of printed circuit boards.

Another embodiment of the invention is a method for fabricating a 3-dimensional synchronous Buck converter. The method is suitable for fast and low-cost batch processing, since all attachments are performed by a single solder material and a single reflow temperature so that a single one-step-fits-all attachment process can be employed. The solder paste is selected so that the solder reflow temperature is higher than the temperature of wire bonding. Further, downhill wire bonding is almost completely avoided. In addition it is preferred that the piece parts, such as leadframe and clips, are provided in strip form and are only singulated after the encapsulation step.

The fabrication method starts with the step of providing a leadframe providing a leadframe, which has a rectangular flat assembly pad and a plurality of terminal leads positioned in line with two opposite sides of the pad; the other pad sides are free of leads. A preferred leadframe metal is copper or a copper alloy in a thickness range from about 150 to 250 μm; other options include aluminum, an iron-nickel alloy, and Kovar™. Both surfaces of the pad have a metallurgical disposition, which facilitates solder wetting and solderability. As an example for copper leadframes, the pad surfaces may have additional plated layers of nickel, palladium and gold. The lead surfaces facing the chips-to-be-assembled are wire bondable to wire of, for example, gold or copper, by a spot-plated layer of gold, for instance. The opposite lead surfaces are preferably solderable.

In the next step, a solder mixture is selected, preferably configured as a tin-based paste, which has a reflow temperature higher than the temperature used for wire bonding (about 220° C.); the paste is used throughout the assembly.

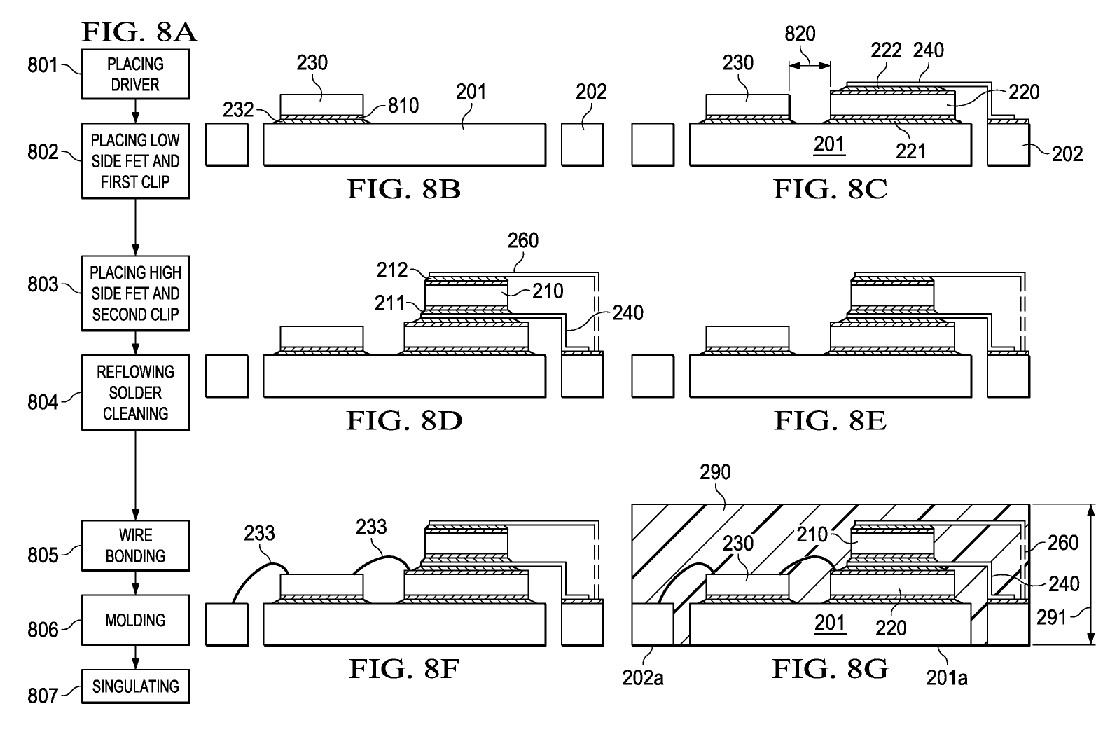

FIG. 8A shows a sequence of steps for fabricating a power supply module according to the invention, and FIGS. 8B to 8G illustrate these process steps schematically. The assembly starts in step 801 by placing a driver-and-controller chip 230 on the leadframe pad 201 using a layer 232 of solder paste with thickness about 25 μm or greater as an adhesive; see FIG. 8B. Solder paste 232 may be dispensed on pad 201 by a syringe, or by screen printing. Chip 230 has back side metallization 810 such as a layer of nickel or titanium-tungsten followed by a layer of palladium) in order to render the back side of semiconductor chip 230 solderable.

In the next step 802, a sync FET die 220 (low side FET) is placed adjacent to driver-and-controller chip 230 onto a layer 221 of solder paste dispensed on pad 201; see FIG. 8C. The placement of FET die 220 is preferably source down; the source of the synchronous FET faces the leadframe pad. In other embodiments, the drain of the sync FET faces the pad. Preferred thickness of solder layer 221 is about 25 μm or greater. In order to keep parasitics as small as possible, the distance 820 between chip 230 and die 220 is preferably selected as narrow as assembly layout rules allow, without risking an accidental merging of the adjacent meniscus of the liquefied solder layers 232 and 221 during the reflow process, which would be coupled with surface tension-induced relative movements of chip 230 and die 220. As an example, for certain solder alloys and layer thicknesses, about 300 μm is a preferred distance.

After placing die 220 source-down on pad 201, a first clip 240 is placed onto a layer 222 of the same solder paste dispensed on the drain terminal of the sync FET die 220. First clip 240, destined to become the switching node of the high current converter, has obtained, by stamping and forming or etching of the starting metal sheet (about 0.2 to 0.3 mm thick), a structure so that concurrently with the placement on the sync FET die a clip portion gets to rest on a layer of the solder paste dispensed on a first set of leads 202 of the leadframe; this set of leads 202 serves as the switching node terminal of the module, connecting to the output inductor and the load.

In the next process step 803, illustrated in FIG. 8D, a control FET die 210 (high side FET) is placed onto a layer 211 of solder paste dispensed on first clip 240. The placement of FET die 210 is preferably source down, facing first clip 240; the drain of the control FET faces second clip 260 to the input voltage V_{IN}. In other embodiments wherein the sync FET die 220 has its source terminal in contact with first clip 240, the drain of the control FET faces first clip 240. As with all other solder layers, the preferred thickness of solder layer 211 is about 25 μm or greater.

After placing die 210 source-down on first clip 240, a second clip 260 is placed onto a layer 212 of solder paste dispensed on the drain terminal of the control FET die 210. Second clip 260, destined to become the connector to the input (V_{IN}) of the high current converter, has obtained, by stamping and forming or etching of the starting metal sheet (about 0.2 to 0.3 mm thick), a structure so that concurrently with the placement on the control FET die a clip portion gets to rest on a layer of solder paste dispensed on a second set of leads of the leadframe. The second set of leads serves as the input terminal of the module, connecting to the input V_{IN}.

In the next process step 804, indicated in FIG. 8E, thermal energy is supplied to raise the temperature for reflowing the layers of solder paste at the solder reflow temperature. If all solder layers are made of the same material, all solder connections can be accomplished concurrently by a single reflow step. This simplifying feature contributes significantly to a low cost of the fabrication method. After lowering the temperature from the solder reflow temperature, wire bonding or ribbon bonding 233 is employed in process step 805, depicted in FIG. 8F, to connect the terminals of the driver-and-control chip 230 to respective leads of the leadframe, and also to the gate and back gate terminals of the sync FET die and the gate terminal of the control FET die. Bonding step 805 avoids downhill bonding almost completely and thus minimizes the well-known reliability issue of wire shorting during the encapsulation step.

In the next process step 806, illustrated in FIG. 8G, the driver-and-control chip 230, the sync FET die 220, the control FET die 210, the first clip 240, the second clip 260, and the wire bonds 233 are encapsulated in a packaging compound 290. On the other hand, the bottom 201a of pad 201 and the bottoms 202a of the leads 202 are left un-encapsulated so that pad bottom surface 201a and lead bottom surfaces 202a can be soldered to a substrate heat sink. Since the packaging thickness over second clip 260 can be kept small, the total thickness 291 of the exemplary module can be kept to 1.5 mm. It is possible to reduce this thickness further by keeping the top surface of second clip 260 un-encapsulated, a feature enabled by the fact that no wire bonding is involved for connecting the drain terminal of the control FET.

For reasons of batch processing and low fabrication cost, it is preferred to provide the leadframe, the first clip, and the second clip in strip form. In process step 807, the encapsulated strip is singulated into discrete module units like the module depicted in FIG. 3. A preferred singulation technique is sawing.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the invention applies not only to field effect transistors, but also to other suitable power transistors.

As another example, the high current capability of the power supply module can be further extended, and the efficiency further enhanced, by leaving the top surface of the second clip un-encapsulated so that the second clip can be connected to a heat sink, preferably by soldering. In this configuration, the hexahedron-shaped module can dissipate its heat from both large surfaces to heat sinks.

It is therefore intended that the appended claims encompass any such modifications or embodiments.

We claim:

1. A power supply system comprising:
a QFN leadframe having a rectangular flat pad and leads positioned in line with two opposite sides of the pad, the other pad sides being free of leads;
a synchronous Buck converter having a synchronous FET die and a control FET die, the control die soldered onto the synchronous die, and the synchronous die soldered onto the pad; and
a driver and controller chip soldered onto the pad adjacent to the converter, wire-bonded to the leads and to the FET dies.

2. The system of claim 1 further having the leadframe pad soldered to a substrate heat sink, which extends beyond the lead-free pad sides.

3. The system of claim 2 wherein all solder comprises the same metal alloy.

4. The system of claim 1 further including an output inductor adjacent to the converter, the inductor soldered to a heat sink in the substrate.

5. The system of claim 1 further including a packaging compound encapsulating the converter and the chip, leaving the pad bottom and leads un-encapsulated.

6. A method for fabricating a power supply system comprising the steps of:
providing a leadframe having a rectangular flat pad and leads positioned in line against two opposite sides of the pad, the other pad edges being free of leads;
placing a driver-and-controller chip and a sync FET die adjacent to each other onto solder paste dispensed on the pad;
placing a first metal clip onto a layer of solder paste dispensed on the sync FET die and onto a layer of solder paste dispensed on a first set of leads;
placing a control FET die onto a layer of solder paste dispensed on the first clip;
placing a second metal clip onto a layer of solder paste dispensed on the control FET die and onto a layer of solder paste dispensed on a second set of leads; and
concurrently reflowing the layers of solder paste above a reflow temperature.

7. The method of claim 6 further including the step of wire bonding the driver-and-control chip to leads, to the sync FET die, and to the control FET die.

8. The method of claim 7 wherein the wire bonding is at a temperature lower than the reflow temperature.

9. The method of claim 8 further including the step of encapsulating the sync FET die, the control FET die, the driver-and-controller chip, the first and second clips and the wire bonds in a packaging compound, leaving the bottom of the pad and the leads un-encapsulated.
